(19) United States
(12) Patent Application Publication
(10) Pub. No.: US 2022/0199323 A1
(43) Pub. Date: Jun. 23, 2022

(54) METHOD TO INDUCE TUNABLE FERROMAGNETISM WITH PERPENDICULAR MAGNETIC ANISOTROPY IN DELAFOSSITE FILMS

(71) Applicant: Rutgers, The State University of New Jersey, New Brunswick, NJ (US)

(72) Inventors: Seongshik Oh, Marlboro, NJ (US); Gaurab Rimal, Highland Park, NJ (US)

(21) Appl. No.: 17/558,057

(22) Filed: Dec. 21, 2021

Related U.S. Application Data
(60) Provisional application No. 63/128,485, filed on Dec. 21, 2020.

(51) Int. Cl. H01F 41/22; H01F 10/12; C23C 16/56; C23C 16/40

(52) U.S. Cl. CPC H01F 41/22; C23C 16/406; C23C 16/56; H01F 10/12

(57) ABSTRACT

A method for inducing tunable ferromagnetism with hydrogen annealing in delafossite films includes obtaining a PdCoO₂ thin film, positioning the PdCoO2 thin film on a substrate, annealing the PdCoO₂ thin film by hydrogenation, and cooling the PdCoO₂ thin film to approximately room temperature.

### CROSS-REFERENCE TO RELATED APPLICATION

This application claims the benefit of and priority to U.S. Provisional Application No. 63/128,485, filed Dec. 21, 2020, which is incorporated herein by reference in its entirety.

### STATEMENT REGARDING FEDERALLY SPONSORED RESEARCH

This invention was made with government support under Grant No. DMR2004125 awarded by the National Science Foundation. The government has certain rights in the invention.

### FIELD OF INVENTION

The present invention relates generally to methods for inducing tunable ferromagnetism with hydrogen annealing in delafossite films.

### BACKGROUND

Most oxides are insulators, but certain transition metal oxides (TMO) can be metallic (conducting) when d-orbitals of the transition metal ions are partially filled. These unoccupied d-orbitals can not only lead to metallic states, but also develop many more intriguing properties due to competition between localized and extended states. High critical temperature superconductivity in cuprates, colossal magnetoresistance in manganites, and multiferroicity in ferrites are some of the well-known examples. Many of these tunable TMO materials are variants of the perovskite family, which has four-fold symmetry. Another family of TMO with a layered triangular lattice are delafossites.

The delafossite family, named after the mineral CuFeO₂, has a general molecular formula of ABO₂ with a three-fold layered crystal structure. The structure can be simply considered as alternating layers of A and BO₂ triangular lattice along the c-axis. The stacking sequence of the layers could result in either rhombohedral (R-3m), as shown in FIG. 1A, or hexagonal (P6₃/mmc) crystal structure. In general, the conduction properties are determined by the monovalent A site. When the A site is occupied by Cu or Ag, the system is usually insulating or semiconducting. On the other hand, Pt or Pd in the A site renders a metallic system. The trivalent B site, however, does not provide charge carriers, but acts to develop magnetism in some delafossites.

The metallic delafossites do not occur naturally. Although they were first synthesized in 1971, research activities were sparse in the following decades. More recently, as the quality of bulk crystals improved, the Pd/Pt based metallic system started to attract significant interest due to their transport properties. For example, in PdCoO₂, Pd is in an unusual 1+ oxidation state and provides one itinerant electron per site, giving an electron density of 1.45×10¹⁵/cm² per Pd layer. The neighboring CoO₂ layer is, on the other hand, insulating. The alternation of conducting Pd layer and insulating CoO₂ layer results in highly anisotropic conductivity, and exotic transport properties such as hydrodynamic transport and ultralow in-plane resistivity. Nonetheless, such unique properties of PdCoO₂ system have been so far observed only in bulk crystals, despite a series of efforts to develop high quality films.

With reference to FIG. 1B, PdCoO₂ films now rival the best metals in terms of room temperature resistivity. Although PdCoO₂ has interesting transport behaviors, it is non-magnetic (weakly paramagnetic). This is because the 3d⁶ electrons in Co³⁺ completely fill the t_{2g} band. All magnetic delafossites, including the metallic PdCrO₂, are antiferromagnetic. At best, only weak signatures of spin-polarization have been observed on the surface of PdCoO₂, presumably due to surface ions with incomplete bonds. In TMOs, antiferromagnetic order is much more common than ferromagnetic order. However, it is sometimes possible to induce ferromagnetic order on otherwise non-magnetic or antiferromagnetic TMO by changing the valence state of the 3d transition metal ion via doping such that its 3d-band becomes partially filled. For example, antiferromagnetic LaMnO₃ can be converted into a ferromagnetic state by substituting Sr for La in the form of La₁₋ₓSrₓMnO₃. If the valence state of Co can be changed from the 3d⁶ configuration, inducing ferromagnetism in PdCoO₂ can be achieved. Unfortunately, there is not a suitable charge dopant for Pd. An alternative way to change the valence state of a transition metal is by hydrogenation.

### SUMMARY

This summary is a high-level overview of various aspects of the invention and introduces some of the concepts that are further detailed in the Detailed Description section below. This summary is not intended to identify key or essential features of the claimed subject matter, nor is it intended to be used in isolation to determine the scope of the claimed subject matter. The subject matter should be understood by reference to the appropriate portions of the entire specification, any or all drawings, and each claim.

Embodiments of the present disclosure relate to a method including the steps of obtaining a PdCoO₂ thin film, positioning the PdCoO₂ thin film on a substrate, annealing the PdCoO₂ thin film by hydrogenation, and cooling the PdCoO₂ thin film to approximately room temperature.

In some embodiments, the step of annealing the PdCoO₂ thin film by hydrogenation includes continuously flowing a gas mixture comprising from 5% to 100% of hydrogen gas.

In some embodiments, the gas mixture includes Argon.

In some embodiments, the annealing temperature is 50° C. to 200° C.

In some embodiments, the step of annealing the PdCoO₂ thin film by hydrogenation includes annealing the PdCoO₂ thin film by hydrogenation for 30 minutes to 15 hours.

In some embodiments, the anneal and cooled PdCoO₂ thin film is a room temperature ferromagnet with out-of-plane anisotropy.

In some embodiments, the annealing of the PdCoO₂ thin film includes heating the PdCoO₂thin film from room temperature to a predetermined temperature at 10° C./min.

In some embodiments, the annealing of the PdCoO₂ thin film includes keeping the PdCoO₂ thin film at the predetermined temperature for a designated time

In some embodiments, the annealed and cooled PdCoO₂ thin film has a sign-tunable anomalous Hall effect.

In some embodiments, the sign-tunable anomalous Hall effect occurs without reversal of a magnetization direction.

In some embodiments, the PdCoO₂ thin film has a thickness of 5.3 nm to 100 nm.

In some embodiments, the substrate comprises Al₂O₃.

In some embodiments, the method further includes growing the PdCoO₂ thin film is grown on the substrate under plasma oxygen.

### BRIEF DESCRIPTION OF THE DRAWINGS

The accompanying drawings are included to provide a further understanding of the disclosure and are incorporated in and constitute a part of this specification, illustrate embodiments, and together with the description explain the principles of the present disclosure.

FIG. 1A is an annular darkfield scanning transmission electron microscopy image for a PdCoO₂ thin film, with a zoomed region showing the atomic layering, in accordance with embodiments described herein;

FIG. 1B is a graph showing a comparison of room temperature resistivity for thin films of various metals, and PdCoO₂, the solid horizontal lines showing the bulk value for the labelled oxides, in accordance with embodiments described herein;

FIG. 2A is a graph showing a Hall effect of 9 nm thick pristine film at room temperature with an ordinary Hall effect, in accordance with embodiments described herein;

FIG. 2B is a graph showing hysteretic anomalous Hall effect (AHE) developments in the film of FIG. 2A after hydrogenation, in accordance with embodiments described herein;

FIG. 2C is a reflection high energy electron diffraction (RHEED) image of a pristine PdCoO₂ film, in accordance with embodiments described herein;

FIG. 2D is a RHEED image of a hydrogenated PdCoO₂ film, in accordance with embodiments described herein;

FIG. 2E is a graph showing out-of-plane x-ray diffraction (XRD) for a pristine PdCoO₂ film, in accordance with embodiments described herein;

FIG. 2F is a graph showing XRD for a hydrogenated PdCoO₂ film, in accordance with embodiments described herein;

FIG. 3A is a graph showing Rutherford backscattering spectrometry (RBS) spectra for 100 nm-thick PdCoO₂ films before and after hydrogenation, in accordance with embodiments described herein;

FIG. 3B is a graph showing elastic recoil detection analysis (ERDA) spectra for the films of FIG. 3A, in accordance with embodiments described herein;

FIG. 3C are transmission electron microscopy (TEM) images for pre and post-hydrogenated PdCoO₂ films and the absence of contrast between atomic layers after hydrogenation resulting from intermixing of Pd and Co, in accordance with embodiments described herein;

FIG. 3D is a schematic model of the structural collapse of PdCoO₂ as a result of hydrogenation, in accordance with embodiments described herein;

FIG. 4A is a graph showing AHE for a 5.3 nm thick PdCoO₂ film annealed at various temperatures (TA), in accordance with embodiments described herein;

FIG. 4B is a graph showing AHE for a 9 nm thick film annealed at T_{A}=200° C. for various anneal time, in accordance with embodiments described herein;

FIG. 4C is a graph showing the dependence of saturated values of anomalous Hall conductivity on longitudinal conductivity of various samples measured at different temperatures, in accordance with embodiments described herein;

FIG. 5 is an image showing RHEED patterns along two high symmetry directions, in accordance with embodiments described herein;

FIG. 6A is a graph of Co 2p x-ray photoelectron spectroscopy (XPS) spectra for pristine and hydrogenated films compared to a PdCo multilayer film, in accordance with embodiments described herein;

FIG. 6B is a graph of and Pd 3p XPS spectra for pristine and hydrogenated films compared to a PdCo multilayer film, with all spectra being normalized to the highest peak for clarity, in accordance with embodiments described herein, in accordance with embodiments described herein;

FIG. 7A is a graph showing ERDA spectra for a 100 nm thick film, in accordance with embodiments described herein;

FIG. 7B is a graph showing RBS spectra for the film of FIG. 7A, in accordance with embodiments described herein;

FIG. 7C is a graph showing an oxygen scattering region of RBS with simulations for various oxygen concentrations, in accordance with embodiments described herein;

FIG. 8A is a graph showing the magnetic properties of a 9 nm thick hydrogenated film, in accordance with embodiments described herein;

FIG. 8B is another graph showing the magnetic properties of a 9 nm thick hydrogenated film, in accordance with embodiments described herein;

FIG. 9A is a graph showing the temperature dependence of resistivity comparing 9 nm thick pristine and hydrogenated films, in accordance with embodiments described herein;

FIG. 9B is a graph showing the temperature dependence of resistivity comparing 5.3 nm thick pristine and hydrogenated films, in accordance with embodiments described herein;

FIG. 10A is a graph showing AHE for a PdCo multilayer at room temperature, in accordance with embodiments described herein; and

FIG. 10B is a graph showing AHE for a PdCo alloy at low temperature, in accordance with embodiments described herein.

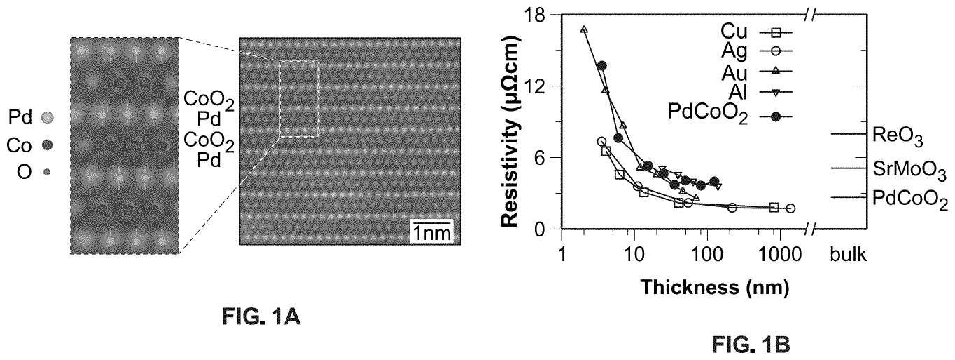

### DETAILED DESCRIPTION

Persons skilled in the art will readily appreciate that various aspects of the present disclosure can be realized by any number of methods and apparatus configured to perform the intended functions. It should also be noted that the accompanying drawing figures referred to herein are not necessarily drawn to scale but may be exaggerated to illustrate various aspects of the present disclosure, and in that regard, the drawing figures should not be construed as limiting.

Described herein are methods of hydrogenation including annealing a sample in a controlled hydrogen embodiment. As described herein, the hydrogenation process results in robust ferromagnetism with out-of-plane anisotropy in PdCoO₂ thin films. In some embodiments, manipulation of the Berry phase of conduction electrons, as manifested by a change of sign in anomalous Hall coefficient, occurs by changing the hydrogenation parameters.

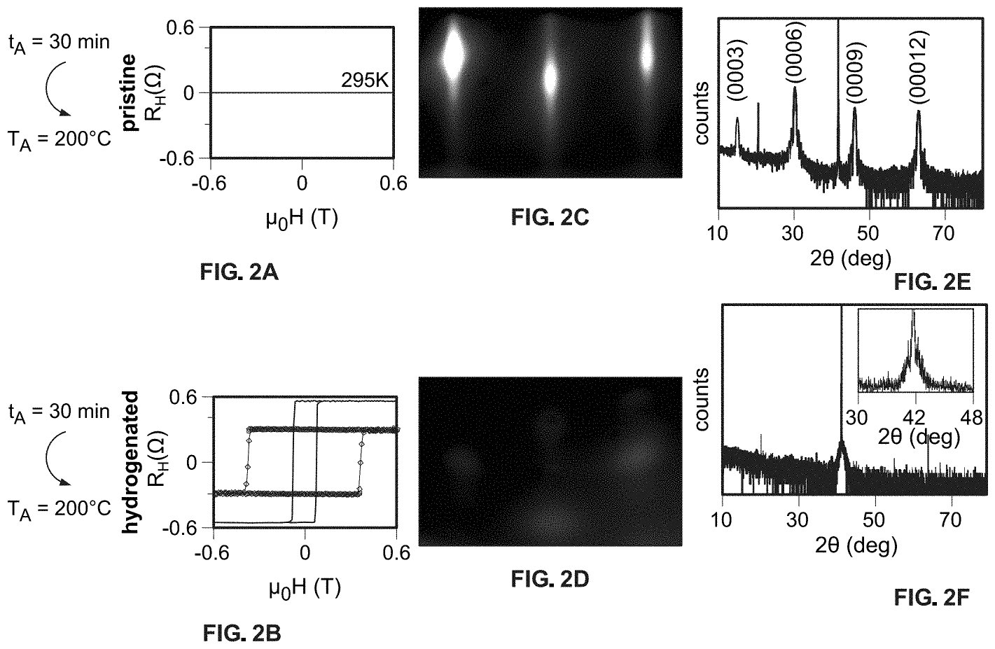

In some embodiments, the present disclosure relates to a method of hydrogen annealing with anneal time (t_{A}) and temperature (T_{A}) as control parameters. In some embodiments, PdCoO₂ films are grown on Al₂O₃ (0001) substrates under plasma oxygen. With reference to FIG. 2A, in an embodiment, a 9 nm thick pristine PdCoO₂ film at room temperature shows an OHE whose linear slope is determined by the sheet carrier density of the film. In an embodiment, after hydrogenation of the 9 nm thick PdCoO₂ film, a noticeable AHE with a sharp and square hysteretic loop appears at room temperature as well as at low temperatures, as depicted in FIG. 2B. In some embodiments, the hydrogenation process converts the non-magnetic film into a ferromagnetic state with strong out-of-plane moment which persists well above room temperature. In some embodiments, magnetization measurements also show clear out-of-plane anisotropy with an estimated Curie temperature around 650 K (supporting information).

In some embodiments, ferromagnetism with out-of-plane anisotropy has great significance from both technological and scientific standpoints. In some embodiments, information can be stored at a much higher density on ferromagnetic materials with out-of-plane anisotropy, and a number of fundamental 2D phenomena such as quantum AHE (QAHE) also require out-of-plane anisotropy. In some embodiments, when common ferromagnetic materials are made thin, the shape anisotropy of the thin film geometry naturally forces the ferromagnetic moment to lie in plane. In some embodiments, Pd/Co multilayers exhibit hybridization and strong spin-orbit coupling provided by Pd onto ferromagnetic Co which achieves the out-of-plane anisotropy.

With reference to FIGS. 2C through 2F, in an embodiment, the diffraction patterns for PdCoO₂ films before and after hydrogenation are depicted. In this embodiments, the diffraction patterns are obtained using both in-plane RHEED and out-of-plane XRD. In an embodiment, the pristine PdCoO₂ film exhibits a bright streaky RHEED pattern, depicted in FIG. 2C, and sharp XRD peaks, depicted in FIG. 2E, corresponding to the (000/) planes of the delafossite phase. In an embodiment, after hydrogenation, the RHEED pattern depicted in FIG. 2D becomes diffuse and spotty, while still maintaining the overall in-plane hexagonal symmetry, as depicted in FIG. 5. FIG. 5 further depicts the RHEED patterns along the two high symmetry directions for the hydrogenated films. In some embodiments, the high symmetry directions are aligned 60° with respect to each other, and the distance along the zeroth and first order spots are off by a factor of √3, which confirms the hexagonal symmetry in the in-plane direction.

In some embodiments, the XRD peaks also collapse to a single, broad peak overlapping with the sapphire (0006) peak: the single XRD peak lies between the locations that would correspond to Pd and Co (111) peaks. In some embodiments, the out-of-plane lattice spacing obtained from XRD is 2.18±0.02° A after hydrogenation, as compared with the nearest Pd—Co layer spacing of 2.95° A in PdCoO₂. In some embodiments, after hydrogenation, the delafossite structure collapses into a new phase with reduced out-of-plane lattice constant. In some embodiments, catalytic activities of PdCoO₂ bulk single crystals result in significant changes to the surface due to hydrogen evolution. In some embodiments, an analysis of how much oxygen and hydrogen are present in the film is conducted by using two composition analysis tools: RBS and ERDA.

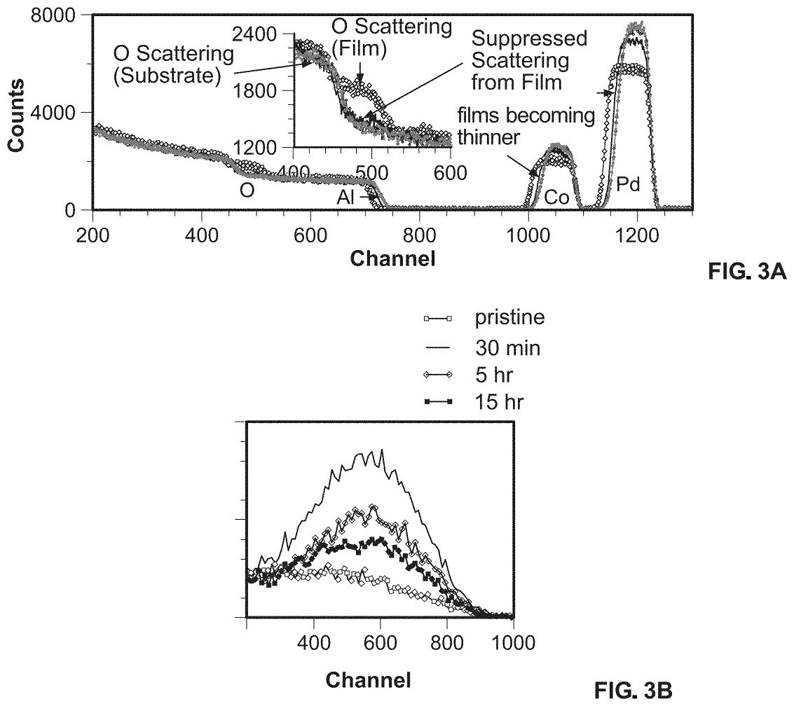

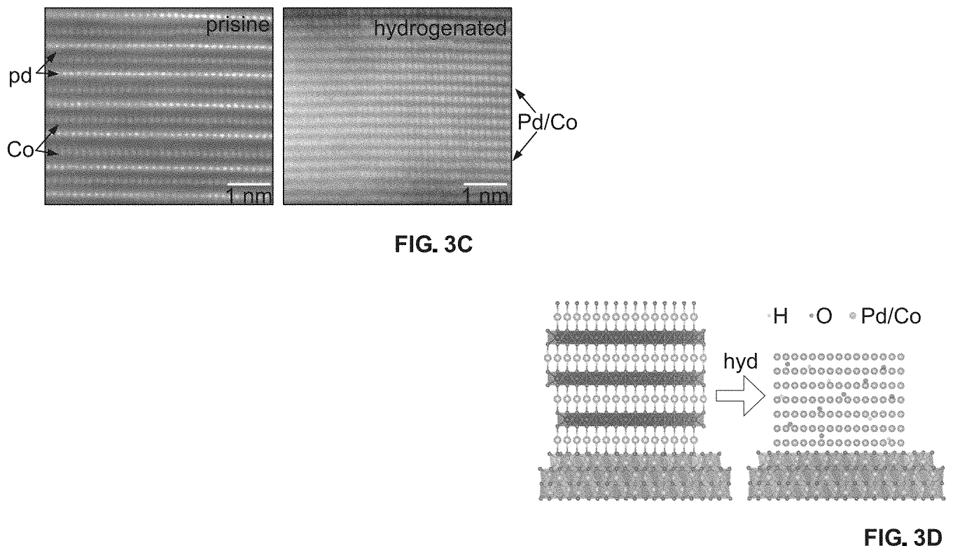

In an embodiment, FIGS. 3A through 3B depict a comparison of RBS and ERDA spectra for 100 nm thick pristine and hydrogenated films. As depicted in the figures, elements corresponding to features in spectra are marked and an inset shows an oxygen region corresponding to backscattering contributions from the film and the substrate. The shift in edges of the backscattering features for various elements, as indicated by the arrows, is due to the reduction of film thickness and the approximate overlap of the curves for the 5 hour and the 15 hour annealed curves indicates that the reduction process reached its limit of negligible oxygen content.

[57] In an embodiment, in the RBS spectra, depicted in FIG. 3A, backscattering due to different elements contributes to intensity features at various regions, as indicated. In an embodiment, since Pd and Co are found only in the film, they appear as a peak/stepped plateau in the spectrum. In an embodiment, Al and O, which are found in the much thicker substrate, show a continuous feature at lower energies (channels). In an embodiment, an additional oxygen feature for the pristine film, emphasized in the inset, starts at a slightly higher energy than the oxygen signal from the substrate. In some embodiments, this extra intensity arises from the oxygen in the film. In some embodiments, with hydrogenation, the oxygen contribution from the film decreases and eventually drops below the detection limit after extended annealing. In some embodiments, with the loss of oxygen in the film, the thickness of the film decreases, which causes the lower-energy edges of the elements to shift to higher energies. In some embodiments, the area under the features of Pd and Co stay unchanged, implying that the content of Pd and Co remains the same.

In an embodiment, ERDA spectra, depicted in FIG. 3B, show that the hydrogen content in the film is the highest after 30 mins of hydrogenation and gradually decreases with further annealing. In some embodiments, in conjunction with the RBS analysis, hydrogen is mainly bonded to oxygen, pulling oxygen out of the film, but not bonded much to Pd or Co. In some embodiments, combined analysis of RBS and ERDA yields a stoichiometry of Pd_{1.03}CoO_{0.83}H_{0.07} after 30 mins of annealing. In some embodiments, after five hours of annealing, the oxygen content drops below the detection limit, and the stoichiometry after annealing for 15 hours becomes Pd_{1.03}CoO_{δ}H_{0.024}, with δ<0.3.

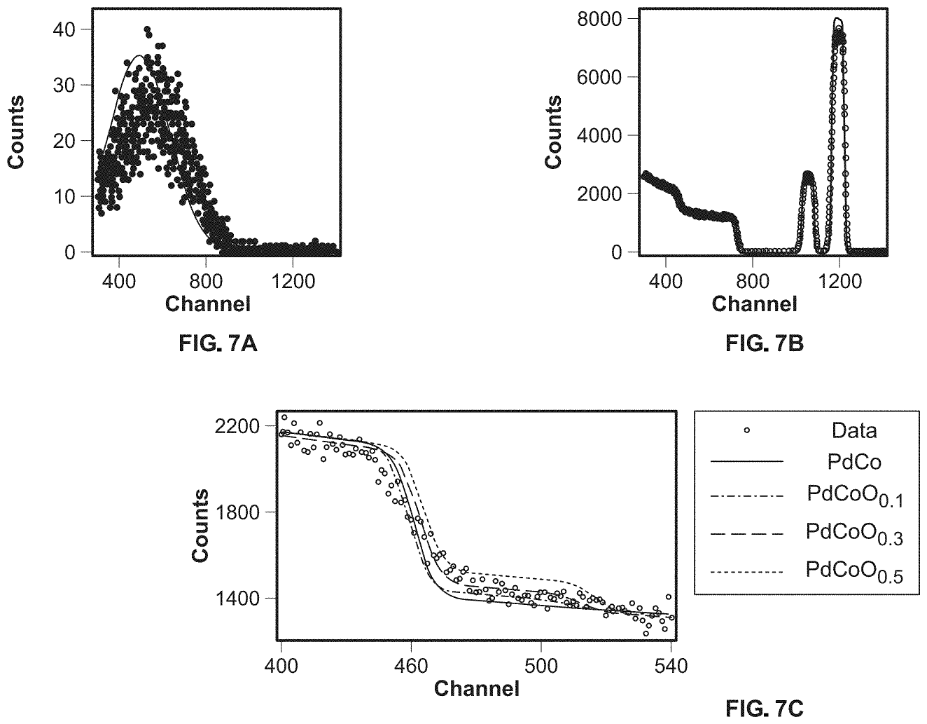

In some embodiments, XPS on these films indicates that both Co and Pd are reduced with hydrogenation. In an embodiment, with reference to FIGS. 7A through 7C, Co 2p peaks shift to higher binding energies after hydrogenation, indicating that Co³⁺ reduces to a lower oxidation state. In some embodiments, reduction of Pd is indicated by the shift of 3d peaks to lower binding energies. In some embodiments, Pd and Co are not fully reduced to the corresponding Pd and Co peaks of pure metals, indicating that the hydrogenated PdCoO₂ film is not a PdCo multilayer.

In some embodiments, RBS, ERDA and XPS studies indicate that the main effect of hydrogenation in PdCoO₂ films is removal of oxygen. In some embodiments, XRD shows a periodic structure, albeit with disorder. In some embodiments, the absence of a half-order peak in XRD indicates a significant mixing between Pd and Co in the new structure. In some embodiments, this intermixing is revealed by TEM, as depicted in FIG. 3C. In some embodiments, in a pristine PdCoO₂ film, a clear distinction can be made between the Pd and Co layers. In some embodiments, in a hydrogenated PdCoO₂ film, there is no contrast among the atomic sites. In some embodiments, the structural change is reproduced by the schematics depicted in FIG. 3D, assuming a hexagonal structure for the hydrogenated system.

In an embodiment, two control samples were synthesized. The first sample was a layered Pd—Co film and the second sample was a fully-alloyed Pd—Co films. In an embodiment, the structural, magnetic and electronic properties of these two films were found to be significantly different from the hydrogenated PdCoO₂ films.

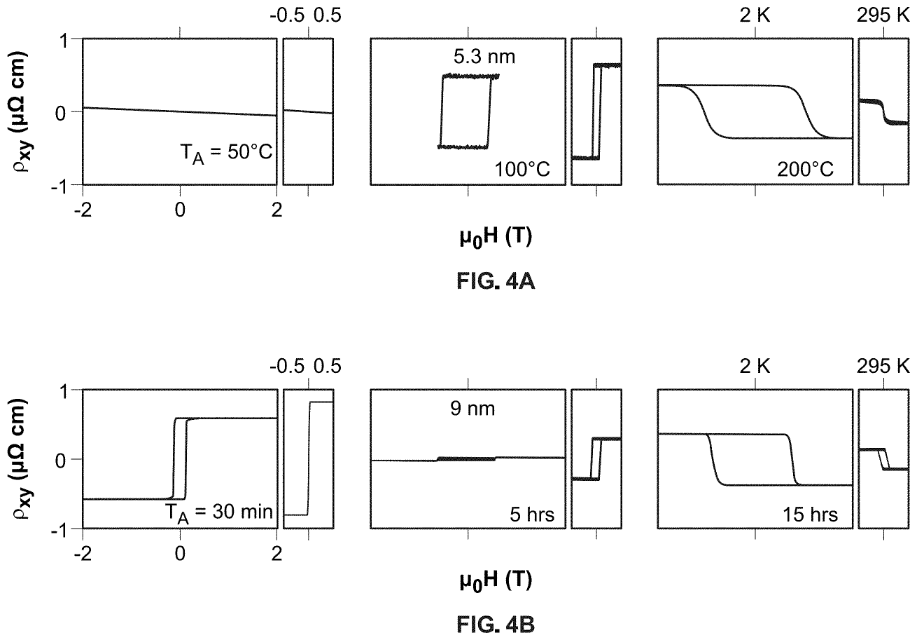

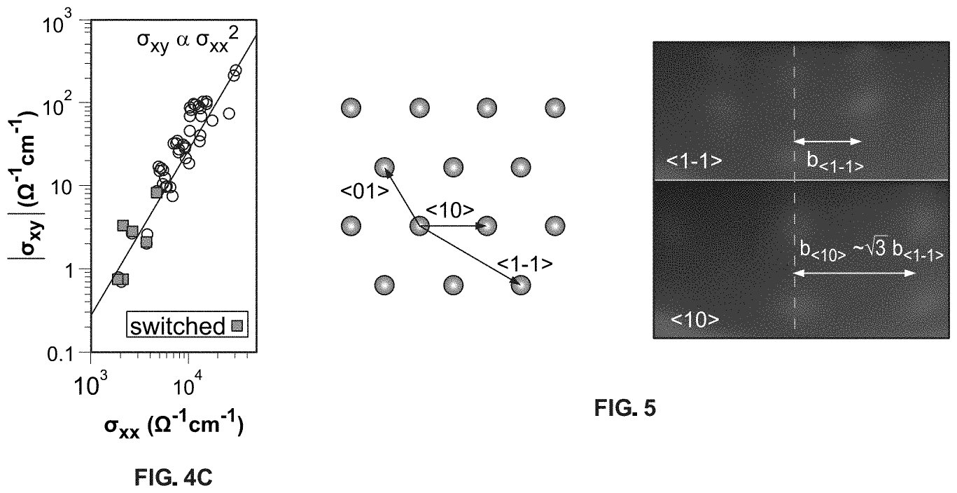

In some embodiments, with reference to FIGS. 4A through 4C, the impact of the structural collapse in hydrogenated PdCoO₂ films results in non-trivial transport behavior. In some embodiments, when the hydrogenation time or temperature increases, the sheet resistance gradually increases.

In some embodiments, the hydrogenation time is 0.5 hours to 15 hours. In other embodiments, the hydrogenation time is 1 hour to 15 hours. In other embodiments, the hydrogenation time is 5 hours to 15 hours. In other embodiments, the hydrogenation time is 10 hours to 15 hours. In other embodiments, the hydrogenation time is 0.5 hours to 10 hours. In other embodiments, the hydrogenation time is 0.5 hours to 5 hours. In other embodiments, the hydrogenation time is 0.5 hours to 1 hour. In other embodiments, the hydrogenation time is 1 hour to 10 hours. In other embodiments, the hydrogenation time is 1 hour to 5 hours. In other embodiments, the hydrogenation time is 5 hours to 10 hours.

In some embodiments, the hydrogenation, or annealing, temperature is 50° C. to 200° C. In other embodiments, the hydrogenation temperature is 100° C. to 200° C. In other embodiments, the hydrogenation temperature is 150° C. to 200° C. In other embodiments, the hydrogenation temperature is 50° C. to 150° C. In other embodiments, the hydrogenation temperature is 50° C. to 100° C. In other embodiments, the hydrogenation temperature is 100° C. to 150° C.

In some embodiments, as the oxygen is removed and the delafossite structure collapses, the characteristic low resistivity values of PdCoO₂ films increase toward modest values of the Pd—Co alloys. In some embodiments, there is a more drastic change in the transverse resistance (a.k.a. Hall resistance), as depicted in FIGS. 4A and 4B. Specifically, FIG. 4A depicts AHE for a 5.3 nm thick film annealed at various temperatures (TA) for tA=30 mins, the curves for low temperature (2 K, −2 T to 2 T) and room temperature (295 K, −0.5 T to 0.5 T) showing robust AHE with out-of-plane anisotropy, and with AHE being absent for TA=50° C., appearing at TA=100° C., and switching signs at TA=200° C., at both low and room temperatures. FIG. 4B depicts AHE for a 9 nm thick film annealed at TA=200° C. for various anneal times, with the sign of AHE switching. In some embodiments, the magnitude as well as the sign of the AHE changes with hydrogenation. In some embodiments, for magnetic materials, the Hall resistivity has contribution from both the ordinary part and the anomalous part, expressed as:

ρ_{xy}(H)=ρ₀H+ρ₁M

where ρ₀ is the ordinary Hall coefficient, ρ₁ is the anomalous Hall coefficient and M is the magnetization. In some embodiments, besides the dependence on magnetization, the anomalous contribution to the Hall resistivity is determined by ρ₁, which depends on both extrinsic factors such as side jumps and skew scattering, and intrinsic factors such as spin-orbit coupling and electronic Berry phase. In some embodiments, as the saturated value of the anomalous Hall conductivity (σ_{xy}) has a well-defined quadratic dependence on the longitudinal conductivity (σ_{xy}over many orders, as depicted in FIG. 4C, the dominant contribution is likely to be of an intrinsic origin. In some embodiments, unlike the magnitude, which is susceptible to extrinsic effects, the sign of the anomalous Hall coefficient should be determined by the Berry curvature at the Fermi level.

In some embodiments, because the Berry curvature changes its sign across band edges, a sign change in AHE is observed when the Fermi level crosses band edges of semiconductors or semimetals via gating or doping.

In some embodiments, considering that the remnant hydrogen in the film is not more than a few percent with respect to the total carrier density of the hydrogenated films, it is unlikely that this sign change is due to a direct doping effect in this high carrier-density system, but more related to intermixing or structural differences, which could subsequently affect the detailed band structure, and thus Berry phase, of the film.

In some embodiments, the present disclosure relates to a method of converting highly conducting, non-magnetic PdCoO₂ film into a strongly ferromagnetic platform with an out-of-plane moment and sign-tunable AHE using a hydrogenation process. In some embodiments, the sign change of AHE occurs without reversal of the magnetization direction. In some embodiments, each of the aforementioned behaviors survive well above room temperature. In some embodiments, PdCoO₂ shares the 3-fold inplane symmetry with other important quantum materials such as graphene, 2D chalcogenides and topological materials indicating forming unprecedented heterostructures for broad magneto-electronic applications.

### EXAMPLES

In an embodiment, PdCoO₂ thin films were obtained. In an embodiment, PdCoO₂ thin films of various thicknesses positioned on Al₂O₃ (0001) substrates (crystec GMBH) were synthesized.

In some embodiments, the PdCoO₂ film has a thickness of 5.3 nm to 100 nm. In other embodiments, the PdCoO₂ film has a thickness of 10 nm to 100 nm. In other embodiments, the PdCoO₂ film has a thickness of 25 nm to 100 nm. In other embodiments, the PdCoO₂ film has a thickness of 50 nm to 100 nm. In other embodiments, the PdCoO₂ film has a thickness of 75 nm to 100 nm.

In some embodiments, the PdCoO₂ film has a thickness of 5.3 nm to 75 nm. In other embodiments, the PdCoO₂ film has a thickness of 5.3 nm to 50 nm. In other embodiments, the PdCoO₂ film has a thickness of 5.3 nm to 25 nm. In other embodiments, the PdCoO₂ film has a thickness of 5.3 nm to 10 nm.

In some embodiments, the PdCoO₂ film has a thickness of 9 nm to 75 nm. In other embodiments, the PdCoO₂ film has a thickness of 10 nm to 50 nm. In other embodiments, the PdCoO₂ film has a thickness of 9 nm to 20 nm. In other embodiments, the PdCoO₂ film has a thickness of 25 nm to 75 nm.

In an embodiment, in-situ RHEED was used to monitor the real-time film growth and in-plane diffraction. In an embodiment, such films were subsequently annealed by continuously flowing a gas mixture in a tube furnace. In some embodiments, the gas mixture is pure hydrogen. In other embodiments, the gas mixture is hydrogen with any inert gas. In some embodiments, the inert gas includes, but is not limited to, nitrogen, argon and helium. In some embodiments, the gas mixture does not include oxygen because oxygen will negate the effect of hydrogenation.

In some embodiments, the gas mixture includes 5% to 100% hydrogen. In other embodiments, the gas mixture includes 10% to 100% hydrogen. In other embodiments, the gas mixture includes 20% to 100% hydrogen. In other embodiments, the gas mixture includes 30% to 100% hydrogen. In other embodiments, the gas mixture includes 40% to 100% hydrogen. In other embodiments, the gas mixture includes 50% to 100% hydrogen. In other embodiments, the gas mixture includes 60% to 100% hydrogen. In other embodiments, the gas mixture includes 70% to 100% hydrogen. In other embodiments, the gas mixture includes 80% to 100% hydrogen. In other embodiments, the gas mixture includes 90% to 100% hydrogen.

In some embodiments, the gas mixture includes 5% to 90% hydrogen. In other embodiments, the gas mixture includes 5% to 80% hydrogen. In other embodiments, the gas mixture includes 5% to 70% hydrogen. In other embodiments, the gas mixture includes 5% to 60% hydrogen. In other embodiments, the gas mixture includes 5% to 50% hydrogen. In other embodiments, the gas mixture includes 5% to 40% hydrogen. In other embodiments, the gas mixture includes 5% to 30% hydrogen. In other embodiments, the gas mixture includes 50% to 20% hydrogen. In other embodiments, the gas mixture includes 5% to 10% hydrogen.

In some embodiments, the gas mixture includes 20% to 70% hydrogen. In other embodiments, the gas mixture includes 50% to 80% hydrogen. In other embodiments, the gas mixture includes 30% to 60% hydrogen. In other embodiments, the gas mixture includes 5% to 60% hydrogen. In other embodiments, the gas mixture includes 80% to 90% hydrogen. In other embodiments, the gas mixture includes 10% to 40% hydrogen. In other embodiments, the gas mixture includes 20% to 30% hydrogen. In other embodiments, the gas mixture includes 50% to 60% hydrogen. In other embodiments, the gas mixture includes 30% to 50% hydrogen.

In some embodiments, the gas mixture includes 5% hydrogen and 95% nitrogen.

In some embodiments, the gas mixture includes 10% hydrogen and 90% Argon.

In an embodiment, the anneal procedure included heating the films from room temperature at 10° C./min to the designated anneal temperature ranging from 50° C. to 200° C., keeping the films at the required temperature (referred to as anneal temperature, T_{A}) for a designated time (referred to as anneal time, t_{A}), and cooling the films naturally to room temperature. In an embodiment, XRD was done with a Panalytical X'Pert 4-circle diffractometer using Cu-Kα radiation (λ=1.54° A). In some embodiments, all the stated thickness is for the delafossite film, and the hydrogenated films may have different (smaller) thickness due to loss of oxygen and collapse of the structure.

In an embodiment, magnetization measurements were performed using a Quantum Design MPMS3 system. In an embodiment, films were mounted on a plastic straw so that the film was either parallel to the magnetic field for in-plane measurements or perpendicular to the magnetic field for out-of-plane measurements. In an embodiment, in the case of zero field cooled (ZFC) measurements, the sample was first cooled without any applied field. Subsequently, in an embodiment, a field of 500 Oe was applied and magnetization was measured during warming. In an embodiment, all transport measurements were performed using a DC Van der Pauw technique.

In an embodiment, RBS and ERDA were performed at an ion scattering facility using 2 MeV He²⁺ ions. In some embodiments, RBS and ERDA are two quantitative tools that can respectively detect the change in oxygen and hydrogen content in the film. In an embodiment, in RBS, 2 MeV He-4 ions are backscattered from elements in the film heavier than the He-4 ions. In an embodiment, quantitative intensity and energy analysis allows measurement of the areal density of the elements in the film. In this case we measure the content of Pd, Co and O in our film. In an embodiment, the overall spectrum is directly influenced by the atomic species as well as the thickness of the film, and fitting can yield the elemental depth profile as well as the absolute values of the concentration of atomic species. In an embodiment, with ERDA, also known as forward recoil scattering, measuring the content of an element that is lighter than the source is performed, by measuring the recoiled atomic species in the forward direction.

In an embodiment, samples used in the annular dark-field scanning transmission electron microscopy (ADF STEM) measurements were prepared by mechanically polishing cross-sectional samples using progressively finer diamond lapping papers on a Multiprep polisher. In an embodiment, the final polishing step was performed with 0.5 μm lapping paper, with the sample uniformly 20 μm thin, as confirmed with optical microscopy. In an embodiment, the polished samples were then ion milled using a Fischione 1010 argon ion miller. In an embodiment, starting with ion accelerating voltage of 3 kV the samples were milled until a hole appeared. In an embodiment, a subsequent cleaning step was performed at a voltage of 0.5 kV to remove the amorphous re-deposition from high energy milling. In an embodiment, scanning transmission electron microscopy was then performed using a NION UltraSTEM 100 at an accelerating voltage of 100 kV, which was corrected for fifth order spherical aberrations. In an embodiment, the images were collected using an annular dark field detector with the collection angles from 84-200 mrad. In an embodiment, images were collected with a pixel dwell time of 4 μs, and each image pair was collected with scan angles parallel and perpendicular to the film-substrate interface and were subsequently corrected for scan drift using a previously developed procedure.

### Symmetry of Hydrogenated Films

With reference to FIG. 5, in an embodiment, the RHEED patterns along the two high symmetry directions are depicted for the hydrogenated PdCoO₂ films. In an embodiment, the high symmetry directions are aligned 60° with respect to each other, and the distance along the zeroth and first order spots are off by a factor of √3, which confirms the hexagonal symmetry in the in-plane direction.

### Reduction of Pd and Co After Hydrogenation

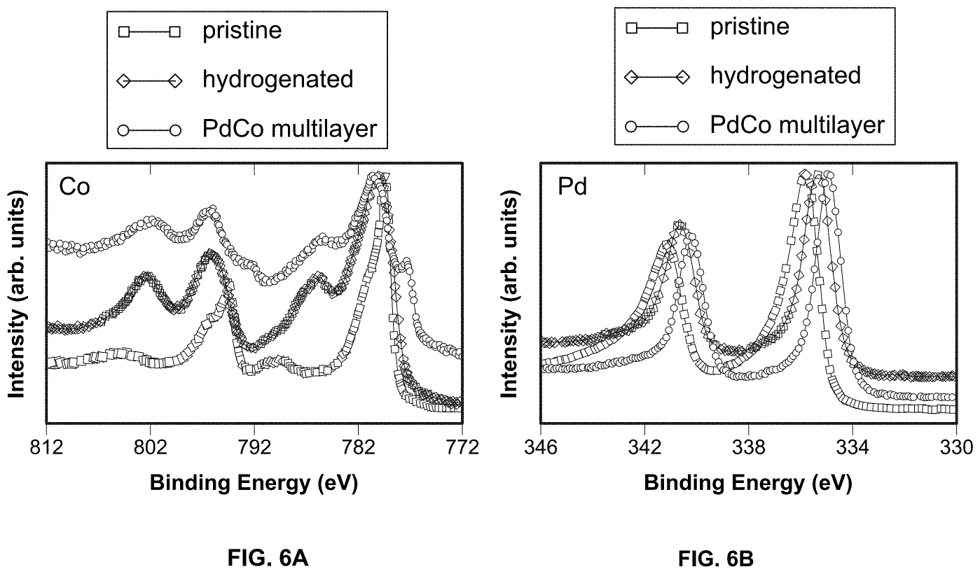

With reference to FIGS. 6A and 6B, in an embodiment, XPS was used to verify that Pd and Co are reduced after hydrogen annealing. As shown in FIGS. 6A and 6B, in an embodiment, Co 2p peaks shift to higher binding energies after hydrogenation and suggests Co³⁺ reducing to lower oxidation states. In an embodiment, reduction of Pd is suggested by the shift of 3d peaks to lower binding energies. In an embodiment, Pd and Co are not fully reduced to the corresponding Pd and Co peaks of pure metals, indicating that the hydrogenated PdCoO₂ film is not a PdCo multilayer.

### Oxygen Loss and Film Stoichiometry

With reference to FIGS. 7A through 7C, in an embodiment, for each of the PdCoO₂ films provided in Table 1, through RBS it was found that oxygen is removed from the films due to hydrogen annealing. In an embodiment, ERDA was also utilized to determine the hydrogen content in the films. In an embodiment, the stoichiometries of the films are determined from the RBS and ERDA results, as depicted in FIGS. 7A and 7B and outlined in Table 1. Furthermore, in an embodiment, since the 5 hours and 15 hours' time period of annealed films do not show any oxygen backscattering feature from the film, the possible error in the determination of the oxygen content in the theoretical curves was simulated. In an embodiment, considering the background noise, any oxygen content lower than PdCoO_{0.3} will not be resolvable, as depicted in FIG. 7C. In some embodiments, it cannot be determined whether the films are fully reduced or if there is still low level of oxygen remaining after the hydrogenation process.

TABLE 1
Comparison of the areal density (in atoms/cm²) and stoichiometry of elements
for various anneal durations determined from fits of RBS and ERDA spectra.

| | Pd density | Co density | O density | H density | Film |
|---|---|---|---|---|---|
| tA | (10¹⁵ at/ | (10¹⁵ at/ | (10¹⁵ at/ | (10¹⁵ at/ | composition |
| (hrs) | cm²) ± 2% | cm²) ± 2% | cm²) ± 5% | cm²) ± 5% | (δ < 0.3) |
| pristine | 250 | 244 | 481 | — | Pd1.03CoO1.97 |
| 0.5 | 258 | 251 | 208 | 18 | Pd1.03CoO0.83H0.07 |
| 5 | 252 | 244 | — | 9 | Pd1.03CoOδH0.037 |
| 15 | 255 | 248 | — | 6 | Pd1.03CoOδH0.024 |

### Magnetic Properties

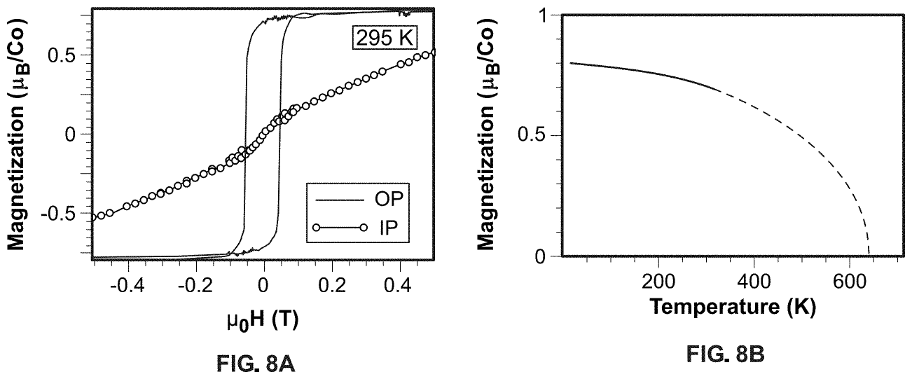

With reference to FIGS. 8A and 8B, graphs showing the magnetic properties of 9 nm thick hydrogenated films are depicted. In an embodiment, ferromagnetism is readily observed in the hydrogenated films. In an embodiment, FIGS. 8A and 8B depict magnetic hysteresis and the temperature dependence of magnetization for a 9 nm thick film. Specifically, FIG. 8A depicts hysteresis loops at room temperature along out-of-plane and in-plane directions, with the easy axis of magnetization along the out-of-plane direction. FIG. 8B depicts the temperature dependence of out-of-plane magnetization for a zero field cooled film, with the dashed line showing fit to the data. In an embodiment, the hysteresis loops clearly reveal out-of-plane anisotropy. In an embodiment, curie temperature of around 650 K is obtained by fitting the temperature dependence of magnetization.

### Other Transport Properties

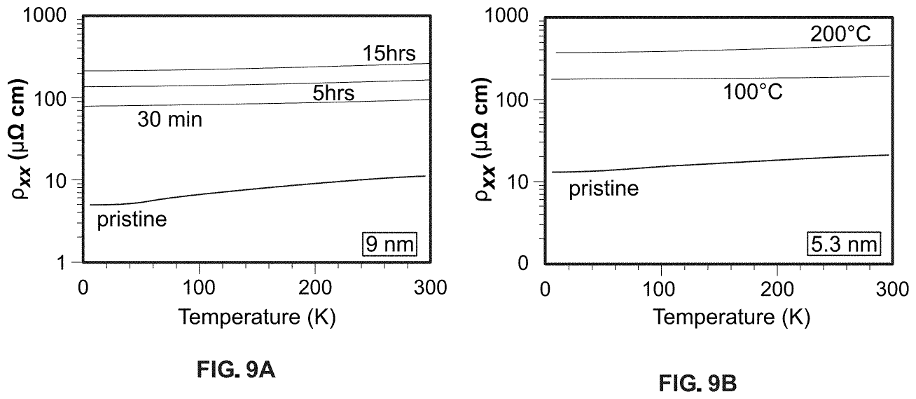

With reference to FIGS. 9A and 9B, in an embodiment, after hydrogenation, not only the Hall resistance but also all the other transport properties change substantially. FIGS. 9A and 9B are graphs depicting the temperature dependence of resistivity comparing pristine PdCoO₂ films with hydrogenated PdCoO₂ films. Specifically, FIG. 9A depicts 9 nm thick films annealed at 200° C. for various durations and FIG. 9B depicts 5.3 nm thick films annealed at various temperatures for 30 minutes. In some embodiments, the resistivity of the films gradually increases with anneal time and temperature. In some embodiments, the areal carrier densities of the hydrogenated films are higher (around twice) than those of the pristine films, suggesting that both Co and Pd may contribute carriers. In some embodiments, the carrier density remains almost the same throughout the sign change of AHE, suggesting that the sign change is not related to the change in Fermi level.

Comparison with PdCo Alloy and Multilayer Films

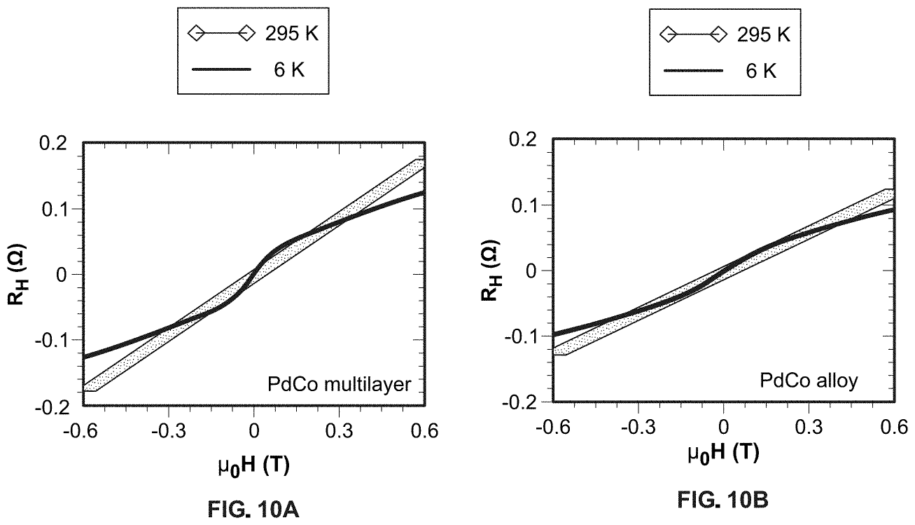

With reference to FIGS. 10A and 10B, two control samples were created to compare with the hydrogenated PdCoO₂ films: (1) a PdCo multilayer with an alternating atomic-layer of Pd and Co so that the layering sequence is as close as possible to that of PdCoO₂, and (2) a PdCo alloy, where Pd and Co are co-deposited for maximal mixing.

In an embodiment, as depicted in FIGS. 10A and 10B, both of these films exhibit only weakly magnetic behavior without any sign of out-of-plane anisotropy in AHE. In some embodiments, the magnetic properties of the Pd—Co system are very sensitive to their structural details.

The subject matter described above is provided by way of illustration only and should not be construed as limiting. Various modifications and changes may be made to the subject matter described herein without following the example embodiments and applications illustrated and described, and without departing from the true spirit and scope of the present disclosure, which is set forth in the following claims.

What is claimed is:

1. A method comprising:
obtaining a PdCoO₂ thin film;
positioning the PdCoO₂ thin film on a substrate;
annealing the PdCoO₂ thin film by hydrogenation; and
cooling the PdCoO₂ thin film to approximately room temperature.

2. The method of claim 1, wherein the annealing of the PdCoO₂ thin film by hydrogenation includes continuously flowing a gas mixture comprising from 5% to 100% of hydrogen gas.

3. The method of claim 2, wherein the gas mixture includes Argon.

4. The method of claim 2, wherein the annealing occurs at a temperature of 50° C. to 200° C.

5. The method of claim 1, wherein the annealing of the PdCoO₂ thin film by hydrogenation includes annealing the PdCoO₂ thin film by hydrogenation for 0.5 hours to 15 hours.

6. The method of claim 1, wherein the annealing of the PdCoO₂ thin film includes heating the PdCoO₂thin film from room temperature to a predetermined temperature at 10° C./min.

7. The method of claim 6, wherein the annealing of the PdCoO₂ thin film includes keeping the PdCoO₂ thin film at the predetermined temperature for a designated time.

8. The method of claim 1, wherein the annealed and cooled PdCoO₂ thin film is a room temperature ferromagnet with out-of-plane anisotropy.

9. The method of claim 1, wherein the annealed and cooled PdCoO₂ thin film has a sign-tunable anomalous Hall effect.

10. The method of claim 9, wherein the sign-tunable anomalous Hall effect occurs without reversal of a magnetization direction.

11. The method of claim 1, wherein the PdCoO₂ thin film has a thickness of 5.3 nm to 100 nm.

12. The method of claim 1, wherein the substrate comprises Al₂O₃.

13. The method of claim 1, further comprising growing the PdCoO₂ thin film is grown on the substrate under plasma oxygen.
